(19) United States
(12) Patent Application Publication
(10) Pub. No.: US 2025/0095698 A1
(43) Pub. Date: Mar. 20, 2025

(54) HIGH SPEED MEMORY CIRCUIT ARCHITECTURE WITH IMPROVED AREA AND POWER EFFICIENCY

(71) Applicant: QUALCOMM Incorporated, San Diego, CA (US)

(72) Inventors: Sonia GHOSH, San Diego, CA (US); Xiao CHEN, San Diego, CA (US); Chi-Jui CHEN, San Diego, CA (US)

(21) Appl. No.: 18/469,989

(22) Filed: Sep. 19, 2023

(51) Int. Cl. G11C 7/10; G11C 7/06; G11C 7/12

(52) U.S. Cl. CPC G11C 7/1012; G11C 7/065; G11C 7/1069; G11C 7/12

(57) ABSTRACT

A random-access memory has its bitcells arranged into a first pair of banks and a second pair of banks. The first pair of banks and second pair of banks are separated by a central controller that contains sense amplifiers and write drivers for the first pair of banks and for the second pair of banks.

### TECHNICAL FIELD

The present application relates generally to memory circuits and, more specifically, to a memory circuit architecture with improved area and power efficiency

### BACKGROUND

Computing devices may include random-access memory (RAM) implemented as static RAM (SRAM), dynamic RAM (DRAM), as well as various read-only memories (ROMs). RAM may be implemented within a processor, such as a central processing unit (CPU), graphics processing unit (GPU), or outside of a processor.

For a given memory design, there may be competition between density (i.e. area savings) and performance (i.e., speed). For instance, a multi-bank memory device may be designed to maximize density at the expense of the operating speed. On the other hand, a multibank memory device may be designed to increase the operating speed at the expense of density.

Accordingly, there is a need in the art for multi-bank memory architectures that achieve a better trade-off between performance and area.

### SUMMARY

In accordance with an aspect of the disclosure, a memory is provided that includes: a first bank of bitcells arranged into a first plurality of columns; a first plurality of read column multiplexers coupled to the first plurality of columns, the first plurality of read column multiplexers being located adjacent a first edge of the first bank of bitcells; a second bank of bitcells arranged into a second plurality of columns, wherein the first edge of the second bank of bitcells is positioned to face the first edge of the first bank of bitcells; a second plurality of read column multiplexers coupled to the second plurality of columns, the second plurality of read column multiplexers being located adjacent the first edge of the second bank of bitcells; a plurality of read circuits being located adjacent a second edge of the second bank of bitcells; and a first plurality of read bit lines coupled to the first plurality of read column multiplexers, the second plurality of read column multiplexers, and the plurality of read circuits.

In accordance with another aspect of the disclosure, a method of reading from a memory is provided that includes: coupling a pair of local bit lines from a first selected column of bitcells from a first bank of bitcells through a first read column multiplexer to a first pair of read bit lines during a first read operation, wherein the first pair of read bit lines extend from the first read column multiplexer and across a second bank of bitcells to a first sense amplifier; sensing a first bit in the first sense amplifier during the first read operation; coupling a pair of local bit lines from a selected column of bitcells in the second bank of bitcells through a second read column multiplexer to the first pair of read bit lines during a second read operation, wherein the second read column multiplexer and the first read column multiplexer are both positioned between the first bank of bitcells and the second bank of bitcells; and sensing a second bit in the first sense amplifier during the second read operation.

In accordance with yet another aspect of the disclosure, a memory is provided that includes: a first bank of bitcells arranged into a first plurality of columns; a first plurality of write column multiplexers coupled to the first plurality of columns, the first plurality of write column multiplexers being located adjacent a first edge of the first bank of bitcells; a second bank of bitcells arranged into a second plurality of columns, each column in the second plurality of columns extending from a first edge of the second bank of bitcells to a second edge of the second bank of bitcells, wherein the first edge of the second bank of bitcells faces the first edge of the first bank of bitcells; a second plurality of write column multiplexers coupled to the second plurality of columns, the second plurality of write column multiplexers being located adjacent the first edge of the second bank of bitcells; a plurality of write drivers positioned adjacent the second edge of the second bank of bitcells; and a first plurality of write bit lines coupled to the first plurality of write column multiplexers, the second plurality of write column multiplexers, and the plurality of write drivers.

Finally, in accordance with another aspect of the disclosure, a memory is provided that includes: a first pair of banks; a second pair of banks; a sense amplifier located between the first pair of banks and the second pair of banks; a first read column multiplexer configured to couple a pair of local bit lines for an addressed column of bitcells from a first bank in the first pair of banks to a first pair of output nodes; a second read column multiplexer configured to couple a pair of local bit lines for an addressed column of bitcells from a second bank in the first pair of banks to the first pair of output nodes; and a first pair of read bit lines coupled between the first pair of output nodes and the sense amplifier.

These and other advantageous features may be better appreciated through the following detailed description.

### BRIEF DESCRIPTION OF THE DRAWINGS

FIG. 1 is a diagram of an example multi-bank memory in accordance with an aspect of the disclosure.

FIG. 2A is a diagram of the column multiplexers in the read path portion of a local data path circuit for a multi-bank memory implementation with a two-to-one column multiplexing in accordance with an aspect of the disclosure.

FIG. 2B is a diagram of a local bit line pre-charge circuit for the read path portion of FIG. 2A in accordance with an aspect of the disclosure.

FIG. 3 is a diagram of the column multiplexers in the write path portion of a local data path for an implementation with a two-to-one column multiplexing in accordance with an aspect of the disclosure.

FIG. 4 is a cross-sectional view of an integrated circuit memory with two-to-one column multiplexing in accordance with an aspect of the disclosure.

FIG. 5 is a diagram of a read path portion of a global input/output circuit in accordance with an aspect of the disclosure.

FIG. 6 is a diagram of a write path portion of a global input/output circuit in accordance with an aspect of the disclosure.

FIG. 7 is a flowchart for a method of reading from a memory in accordance with an aspect of the disclosure.

FIG. 8 illustrates some example electronic systems including an integrated circuit with a multi-bank memory in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

Various implementations provided herein include a multi-bank memory architecture that offers an improved balance between performance and density. To provide a better appreciation of the challenges in achieving the advantageous balance between performance and density disclosed herein, some memory concepts will first be discussed. In a static random-access memory (SRAM), the bitcells are arranged into rows and columns. Each column is traversed by a pair of bit lines whereas each row is traversed by at least one word line. With regard to this arrangement by rows and columns, a memory may have a relatively large number of bitcells. If such a large number of bitcells were arranged into a single array, the resulting capacitance on the bit lines and word lines may become too large. It thus improves performance to arrange the bitcells into banks. Each bank has its own columns such that a column in one bank is not shared by any other bank. In this fashion, the bit line and word line capacitance may be kept to manageable levels.

The column pitch in modern memories is relatively small such that a sense amplifier may not fit within the width of a single column. A write column multiplexer may thus be used to couple the sense amplifier to a selected column from a group of multiplexed columns. Each row of bitcells may thus have word interleaving. The number of words interleaved into each row then determines the corresponding column multiplexing. For example, suppose that each row of bitcells in a bank may store two interleaved words. The write column multiplexers for such a bank would then be 2:1 write column multiplexers. The read column multiplexers would be configured analogously. A write driver couples through corresponding ones of the write column multiplexers to write to addressed columns. Similarly, a sense amplifier couples through corresponding ones of the read column multiplexers to read from addressed columns. With respect to the arrangement of the bitcells into banks, a memory designer must also consider where to locate the corresponding read and write column multiplexers, the sense amplifiers, and the write drivers.

For example, consider a memory having a first pair of banks separated from a second pair of banks by a central controller. Each pair of banks could have its own sense amplifiers and write drivers that couple to the pair through corresponding read and write column multiplexers, respectively. In such a memory, the sense amplifiers and write drivers for a pair of banks as well as the read and write column multiplexers may be deemed to form a local data path region that is arranged between the banks in the pair. The first pair of banks thus has its own shared sense amplifiers and write drivers in the corresponding local data path region. Similarly, the second pair of banks has its own shared sense amplifiers and write drivers in its corresponding local data path region. The sense amplifiers in each local data path region may then couple to the central controller through corresponding data output lines. Global write bit lines may also couple from the central controller to the write drivers in the local data path regions. The central controller may thus also be deemed to form part of a global input/output (global read and write paths) to the two pairs of banks. Each column multiplexer corresponds to a single input/output (I/O) in the global input/output.

Note that in such a memory the read and write operations may be relatively fast due to the sense amplifiers and the write drivers being located in the local data path region between the banks. But density (the area occupied on the semiconductor die by the corresponding devices) is lowered because of the duplication of the sense amplifiers and write drivers for each pair of banks. A multi-bank memory is thus disclosed herein that provides the same or better performance as such a sense-amplifier/write-driver-integrated-local-data-path-region memory yet has decreased power consumption and improved density (occupying less space on a semiconductor die).

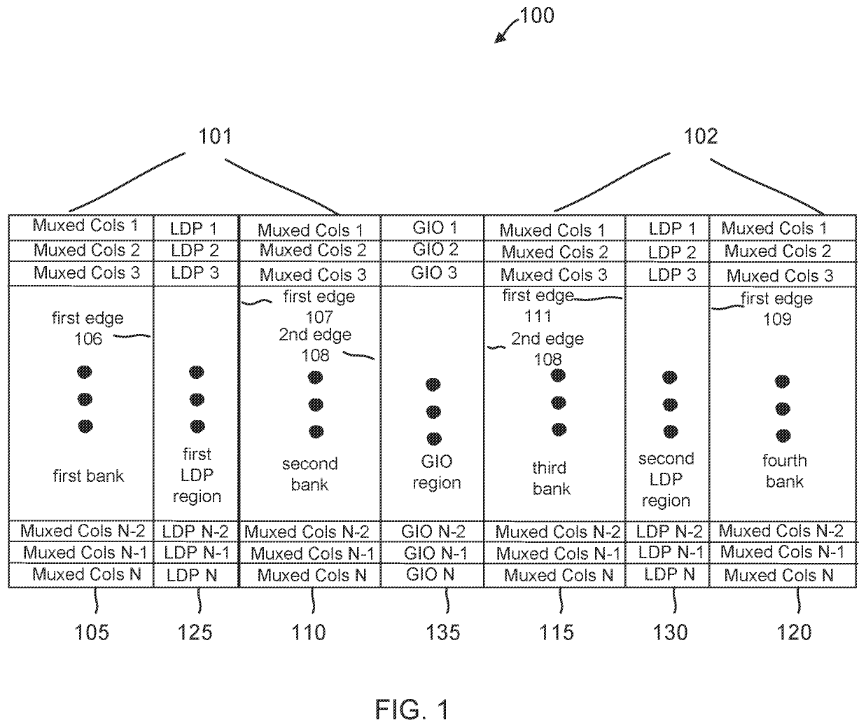

An example multi-bank memory 100 is shown in FIG. 1. In the multi-bank memory 100 there are four banks but it will be appreciated that the memory concepts disclosed herein may be readily extended to memories with more than four banks. A first pair 101 of banks includes a first bank 105 and a second bank 110. Similarly, a second pair 102 of banks includes a third bank 115 and a fourth bank 120. A first local data path (LDP) region 125 is situated between the first bank 105 and the second bank 110 whereas a second LDP region 130 intervenes between the third bank 115 and the fourth bank 120. A global input/output (GIO) region 135 is situated between the first pair 101 of banks and the second pair 102 of banks. To provide an advantageous balance between performance and density, the LDP regions 125 and 130 do not contain sense amplifiers nor do they contain write drivers. Instead, the sense amplifiers and write drivers are located within the GIO region 135.

With regard to the positioning or location of the first LDP region 125 between the first bank 105 and the second bank 110, the first bank 105 may be deemed to have a first edge 106 facing the first LDP region 125. In particular, the first bank 105 will occupy a certain contiguous portion of a semiconductor die. First edge 106 represents a border or edge of such a region that is adjacent the first LDP region 125. Similarly, the second bank 110 may be deemed to have a first edge 107 facing the first edge 106 of the first bank 105 and the first LDP region 125 and have an opposing second edge 108 that faces the GIO region 135. The second bank 110 thus is situated between the first LDP region 125 and the GIO region 135. The third bank 115 and the fourth bank 120 are arranged analogously with respect to the GIO region 135 and the second LDP region 130. The fourth bank 120 may be deemed to have a first edge 109 facing the second LDP region 130. Similarly, the third bank 115 may be deemed to have a first edge 111 facing the first edge of the fourth bank 120 and the second LDP region 130 and have an opposing second edge 112 that faces the GIO region 135.

Each bank has a plurality of columns of bitcells that are multiplexed by corresponding read and write column multiplexers. In the following discussion, the term “column multiplexer” without further limitation is used for brevity as a generic designation of either a read column multiplexer or a write column multiplexer. The resulting number of read and write column multiplexers for each bank depends upon the magnitude of the word interleaving as discussed previously. More generally, if M words are interleaved into each row of bitcells for a bank, then each column multiplexer selects from a corresponding multiplexed group of M columns (M being a plural positive integer). The number of read column multiplexers (which is equal to the number of write column multiplexers) for each bank depends upon the word size. Should the word size be N bits (N being a plural positive integer), there are thus N multiplexed groups of columns in each bank. The multiplexed groups of columns for each bank may thus be deemed to be indexed from 1 to N. For example, the first bank 105 has a first group of multiplexed columns (Muxed Cols 1), a second group of multiplexed columns (Muxed Cols 2), and so on to an Nth group of multiplexed columns (Muxed Cols N). For illustration clarity, only the first three multiplexed column groups and the final three multiplexed groups of columns are shown in FIG. 1 for each bank. Each multiplexed group of columns is multiplexed by a corresponding write column multiplexer and a corresponding read column multiplexer. There are thus N read column multiplexers and N write column multiplexers for each bank.

To provide a better appreciation of the resulting column multiplexing, consider an implementation of memory 100 in which each row of bitcells has two interleaved words. In such an implementation, M (the magnitude of the word interleaving) is two. With regard to this interleaving, the columns for a bank may be arranged from a first column to a final column. The resulting column index in such a serial arrangement is then either odd or even. For example, the first column and a third column have odd indices whereas a second column and a fourth column have even indices. The columns may then be multiplexed such that each column multiplexer selects from an odd and even column. For example, a first column multiplexer may select from the first column and the second column. Similarly, a second column multiplexer may select from the third column and the fourth column, and so on. More generally, if M words are interleaved into each row of bitcells for a bank, then each column multiplexer selects from M columns (M being a plural positive integer).

In memory 100, each multiplexed group of columns is multiplexed by a corresponding read column multiplexer and a corresponding write column multiplexer that are included within a local data path (LDP) circuit for the multiplexed group of columns. For brevity, the following discussion will refer to a local data path circuit as simply an LDP. For example, with regard to the first bank 105, there is a first LDP (LDP 1) for the first multiplexed group of columns that includes a corresponding read column multiplexer and a corresponding write column multiplexer. This first LDP also includes a corresponding read column multiplexer and a corresponding write column multiplexer for the first multiplexed group of columns in the second bank 110. There are N LDPs for the N multiplexed groups of columns in each of the first bank 105 and in the second bank 110, where N is the word size for memory 100. The first LDP region 125 thus ranges from the first LDP to an Nth LDP (LDP N). The second LDP region 130 is arranged analogously for the third bank 115 and the fourth bank 120 and also ranges from a first LDP to an Nth LDP.

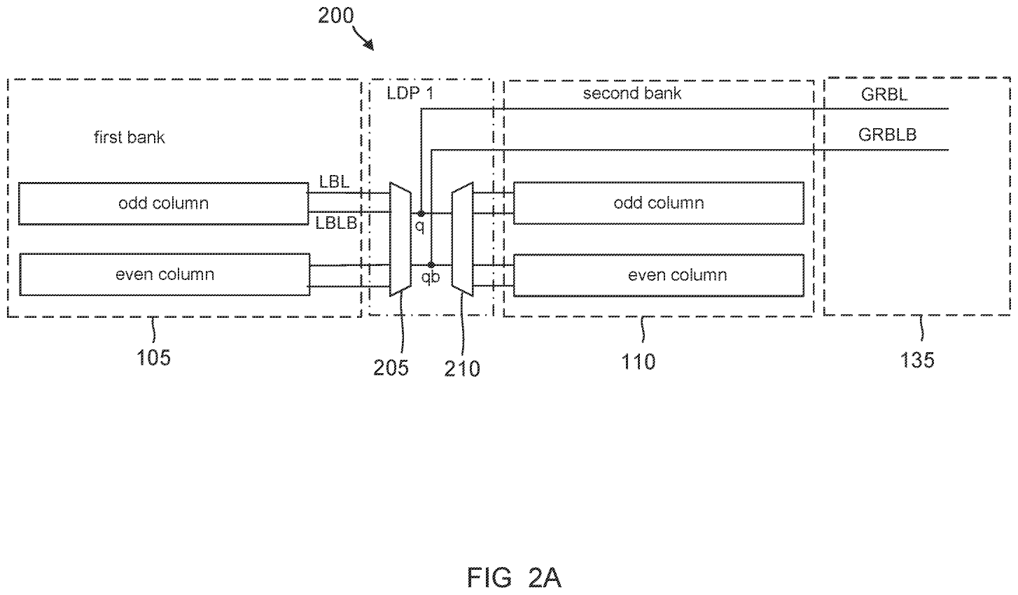

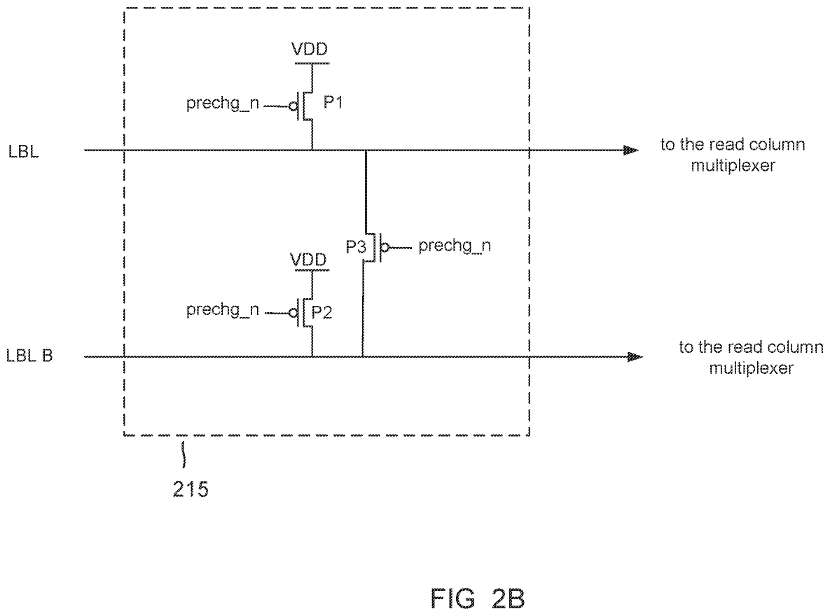

During a read operation, a read column multiplexer selects from its multiplexed group of columns to couple the bit lines in a selected column to a pair of global read bit lines. An example of the read path 200 for the first LDP (LDP 1) for an implementation in which M equals two is shown in FIG. 2A. For illustration clarity, only the read path 200 is shown for LDP 1 in FIG. 2A. The write path for LDP 1 is discussed further below. LDP 1 includes a read column multiplexer 205 for the first bank 105 and a read column multiplexer 210 for the second bank 110. These read column multiplexers are arranged into a pair so as to couple to the same pair of output nodes q and qb. The output node q may also be denoted herein as a positive output node whereas the output node qb may be designated as negative output node. The output node q couples to a global read bit line (GRBL). Similarly, the output node qb couples to a complement global read bit line (GRBLB). The pair of global read bit lines GRBL and GRBLB correspond to the same global output bit. As will be explained further herein, each LDP such as LDP 1 also contains a pair of write column multiplexers coupled to a corresponding pair of global write bit lines. There is thus a global input or output bit specified by the corresponding global write bit pair or the corresponding global read bit line pair, respectively. The global read bit line pair couples to a corresponding sense amplifier in the GIO region 135 whereas the global write bit line pair couples to a corresponding write driver in the GIO region 135. More generally, the global read bit line pair couples to a corresponding read circuit in the GIO region, where the term “read circuit” is defined herein to include within its scope a sense amplifier or a readout latch. Referring again to FIG. 1, it may thus be seen that the GIO region 135 may be subdivided into corresponding GIO circuits for each LDP. There is thus a first GIO circuit (GIO 1) that is shared by the first LDP in the first LDP region 125 and by the first LDP in the second LDP region 130. This first GIO region includes a read circuit such as sense amplifier and also includes a write driver. Similarly, there is a second GIO circuit (GIO 2) that includes a read circuit and a write driver that are shared by the second LDP in the first LDP region 125 and by the second LDP in the second LDP region 130, and so on. Each GIO circuit includes a corresponding sense amplifier and write driver as will be discussed further herein.

In the implementation of FIG. 2A, the word interleaving for the memory banks is a two-to-one interleaving (two words per row of bitcells). Read column multiplexers 205 and 210 are thus two-to-one read column multiplexers such that each read column multiplexer selects between an even column of bitcells and an odd column of bitcells in its corresponding bank. The multiplexed group of columns in such an implementation would thus be a pair of even and odd columns. Depending upon the word size, each bank will have a corresponding number of pairs of even and odd columns of bitcells. For example, if the word size is sixteen bits, then each row of bitcells would have sixteen pairs of odd and even columns. More generally, if the word size is N bits (N being a plural positive integer), then each bank may contain N pairs of even and odd columns. These N pairs of even and odd columns are representative of columns in a first plurality of columns in the first bank 105. Similarly, read column multiplexer 205 is representative of a read column multiplexer from a plurality of read column multiplexers in LDP 1 that couple to the first plurality of columns. As shown in FIG. 2A, this coupling to a selected column by a particular read column multiplexer such as read column multiplexer 205 is performed by the read column multiplexer selecting for the bit lines from the selected column.

During a read operation to the first bank 105, read column multiplexer 205 couples a bit line from the selected or addressed column in the first bank 105 to a global read bit line (GRBL). The bit line from the selected column may thus be designated as a local bit line to distinguish it from the global read bit line. For example, if the selected column in the first bank 105 is the odd column, then the read column multiplexer 205 couples a local bit line (LBL) from the odd column to the global read bit line. During this read operation, the read column multiplexer 205 also couples a complement local bit bine (LBLB) to the complement global read bit line. Alternatively, if the even column were selected, the read column multiplexer 205 couples the even column's local bit lines to the corresponding global read bit lines. The read column multiplexer 210 functions analogously to couple the global read bit line and the complement global read bit line to the bit line and complement bit line (respectively) from the selected column in the second bank 110.

The second LDP through the Nth LDP in the first LDP region 125 also include a pair of read multiplexers, a pair of output nodes q and qb, and a pair of global read bit lines arranged analogously as discussed for the first LDP. Similarly, the N LDPs in the second LDP region 130 are also arranged analogously. In this fashion, there is a pair of global read bit lines coupling from the first pair 101 of banks and another pair of global read bit lines coupling from the second pair 102 of banks to the corresponding GIO for each global input/output bit. For example, if the word size is sixteen bits, the first pair 101 of banks would couple to the GIO region 135 through sixteen pairs of global read bit lines. Similarly, the second pair 102 of banks would couple to the GIO region 135 through another sixteen pairs of global read bit lines. More generally, if the word size is N bits, then the first pair 101 of banks and the second pair 102 of banks would couple to the GIO region 135 through N corresponding pairs of global read bit lines (N being a plural positive integer). GIO region 135 may include a separate sense amplifier for each pair of global read bit lines as will be explained further herein. In an implementation with N pairs of global read bit lines, the GIO region 135 may contain N sense amplifiers (one for each pair of global read bit lines).

Each LDP from the first LDP to the Nth LDP may also include a pre-charge circuit for the pre-charging of the local bit lines in the corresponding pair of banks. For example, a pre-charge circuit 215 for the pre-charging of the local bit lines LBL and LBLB in the even column for read column multiplexer 205 is shown in FIG. 2B. A p-type metal-oxide semiconductor (PMOS) transistor P1 has a source coupled to a power supply node for a memory power supply voltage VDD and a drain coupled to the local bit line LBL. A node for an active-low pre-charge signal (prechg_n) couples to a gate of the P1 transistor. The P1 transistor will thus switch on to charge the local bit line LBL when the pre-charge signal is discharged. Similarly, a PMOS transistor P2 has a source coupled to the power supply node for the memory power supply voltage VDD and a drain coupled to the complement local bit line LBLB. The node for the active-low pre-charge signal (prechg_n) couples to a gate of the P2 transistor. The P2 transistor will thus switch on to charge the complement local bit line LBLB when the pre-charge signal is discharged. To ensure that both local bit lines are pre-charged equally, a PMOS transistor P3 has a source/drain coupled to the local bit line LBL and a source/drain coupled to the complement local bit line LBLB. The node for the pre-charge signal couples to the gate of transistor P3 so that transistor P3 is switched on to couple the local bit lines together during the pre-charge period. In this fashion, both local bit lines are pre-charged equally to the memory power supply voltage VDD while the pre-charge signal is discharged. Each pair of local bit lines would be pre-charged through a corresponding pre-charge circuit such a pre-charge circuit 215.

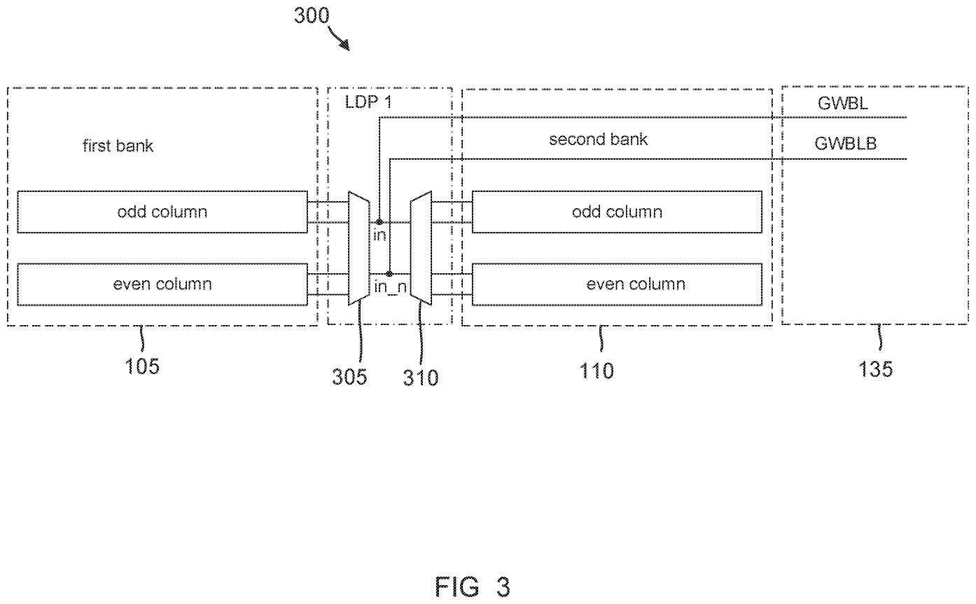

As noted earlier, FIG. 2A illustrated the read path for the first LDP. A write path 300 for the first LDP is shown in FIG. 3 for an implementation in which the column multiplexing is 2:1. The write path 300 includes a write column multiplexer 305 for the first bank 105 and a write column multiplexer 310 for the second bank 110. These read column multiplexers couple to the same pair of input nodes in and in_n. The input node in may also be denoted herein as a positive input node whereas the input node in_n may be designated as negative input node. The input node in couples to a global write bit line (GWBL). Similarly, the input node in_n couples to a complement global write bit line (GWBLB). The pair of global write bit lines GRBL and GRBLB correspond to the same global output bit. The GIO region 135 includes a write driver for driving the global write bit lines during a write operation as will be discussed further herein. For example, suppose that the write operation is the even column in the first bank 105. The pair of global write bit lines would then couple through the write column multiplexer 305 to the corresponding local bit lines in this even column.

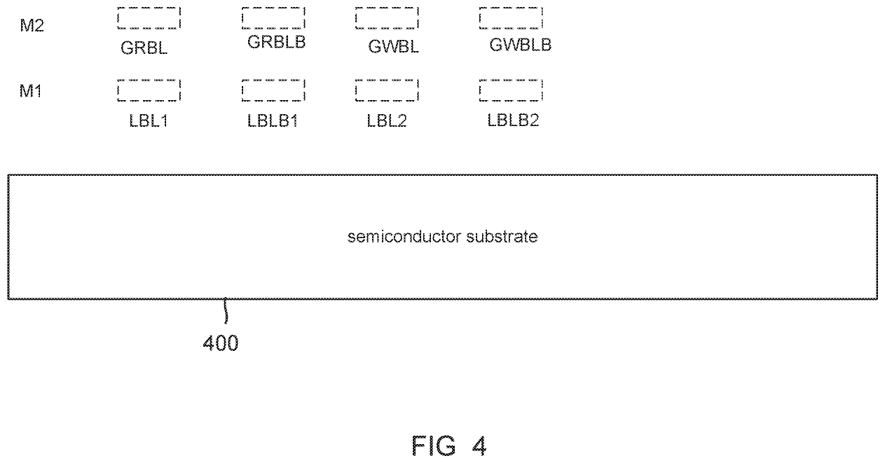

For illustration clarity, the global write bit lines are shown traversing the second bank 110 outside of the pitch for the odd and even column pair in the second bank 110. But the global write bit lines may instead traverse across the second bank 110 within the same column pitch as occupied by the odd and even columns coupled to the write column multiplexer 310. The same column pitch may also be occupied by the global read bit lines. An example semiconductor substrate 400 for the active devices in memory 100 with such a bit line routing is shown in a cross-sectional view in FIG. 4. A first metal layer M1 adjacent the semiconductor substrate 400 for the memory 100 may be patterned to form the local bit lines for a pair of odd and even columns for a 2:1 column multiplexing implementation. The local bit lines for one of the columns may be designated as LBL1 and LBLB1 whereas the local bit lines for the other column may be designated as LBL2 and LBLB2. An adjacent metal layer (for example, an upper metal layer such as a metal layer M2) may be patterned to form the global read bit lines GRBL and GRBLB as well as the global write bit lines GWBL and GWBLB. The global read and write bit lines may thus be designated as “flying” global bit lines since they traverse across the second bank 110 above the corresponding local bit lines. It will be appreciated that the M1 and M2 metal layers are merely exemplary and that other metal layers may be patterned to form the local bit lines and global bit lines discussed herein.

The sense amplifier and write driver for an LDP may be designated as a GIO circuit (designated simply as GIO for brevity in the following discussion). Each LDP corresponds to a GIO such as GIO 1 through GIO N of FIG. 1. For example, the read path of the ith LDP for the first pair 101 of banks couples to the ith GIO through a first pair of global read bit lines, where i is an integer greater than or equal to one and less than or equal to N (recall that N is the word size). Similarly, the read path of the ith LDP for the second pair 102 of banks couples to the ith GIO through a second pair of global read bit lines. In the same fashion, the write path of the ith LDP for the first pair 101 of banks couples to the ith GIO through a first pair of global write bit lines. Finally, the write path of the ith LDP for the second pair 102 of banks couples to the ith GIO through a second pair of global write bit lines. Each GIO thus couples to two pairs of global read bit lines and to two pairs of global write bit lines.

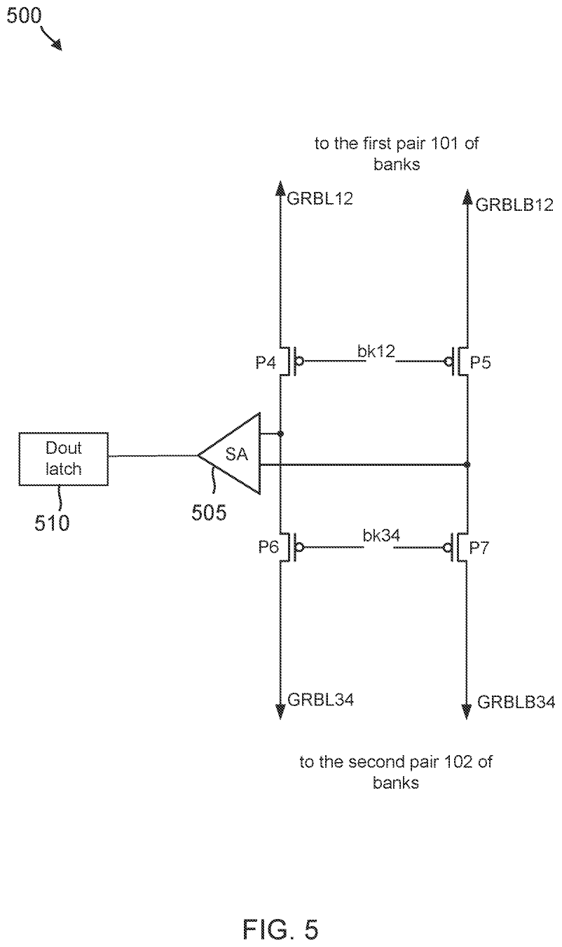

An example GIO will now be discussed. For illustration clarity, the read path for the example GIO will first be discussed followed by a discussion of the write path for the example GIO. An example read path 500 for a GIO such as GIO 1 through GIO N of FIG. 1 is shown in FIG. 5. The global read bit line and the complement global read bit line from the first pair 101 of banks are designated as GRBL12 and GRBLB12, respectively. Similarly, the global read bit line and the complement global read bit line from the second pair 102 of banks are designated as GRBL34 and GRBLB34, respectively. Depending upon whether the read operation is to one of the banks in the first pair 101 of banks or to one of the banks in the second pair 102 of banks, an active-low bank signal bk12 or bk34 is discharged. The default state of these bank signals is to be charged to the memory power supply voltage. Should the read operation be directed to one of the banks in the first pair 101 of banks, the bank signal bk12 is discharged. A node for the bank signal bk12 couples to a gate of a PMOS transistor P4 that couples between the global read bit line GRBL12 and a first input node to a sense amplifier 505. Similarly, the node for the bank signal bk12 couples to a gate of a PMOS transistor P5 that couples between the complement global read bit line GRBLB12 and a second input node to the sense amplifier 505. The sense amplifier 505 may then perform a bit decision so that a resulting output bit may be latched into a data output latch 510. It will be appreciated that a single-ended or a double-ended sensing may be performed by the sense amplifiers disclosed herein.

Conversely, should the read operation be directed to one of the banks in the second pair 102 of banks, the bank signal bk34 is discharged. A node for the bank signal bk34 couples to the gate of a PMOS transistor P6 that couples between the global read bit line GRBL34 and the first input node to the sense amplifier 505. Similarly, the node for the bank signal bk34 couples to a gate of a PMOS transistor P7 that couples between the complement global read bit line GRBLB34 and the second input node to the sense amplifier 505. The sense amplifier 505 may then perform another bit decision so that a resulting output bit may be latched into the data output latch 510.

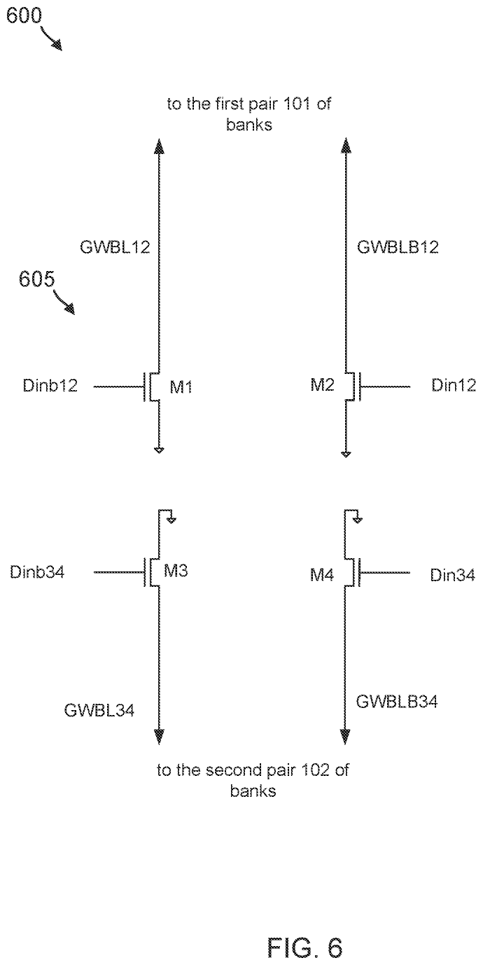

An example write path 600 for a GIO such as GIO 1 through GIO N of FIG. 1 is shown in FIG. 6. In this implementation, a write driver 605 does not practice negative bit line boosting but it will be appreciated that the write driver 605 may be modified to practice such boosting in alternative implementations. The global write bit line and the complement global write bit line from the corresponding LDP for the first pair 101 of banks are designated as GWBL12 and GWBLB12, respectively. Similarly, the global write bit line and the complement global write bit line from the corresponding LDP for the second pair 102 of banks are designated as GWBL34 and GWBLB34, respectively. Prior to a write operation, the global write bit lines GWBL12, GWBLB12, GWBL34, and GWBLB34 are pre-charged through corresponding pre-charge circuits (not shown for illustration clarity) to the memory power supply voltage. Write driver 605 includes an n-type metal-oxide semiconductor (NMOS) transistor M1 having a source coupled to ground and drain coupled to the global write bit line GWBL12. Similarly, write driver 605 includes an NMOS transistor M2 having a source coupled to ground and a drain coupled to the complement global write bit line GWBLB12. During a write operation to one of the banks in the first pair 101 of banks, a data in signal (Din12) is either charged to the memory power supply voltage or discharged depending upon the binary value of the bit to be written. A node for the data in signal Din12 couples to the gate of the transistor M2. Similarly, a node for a complement data in signal (Dinb12) couples to the gate of the transistor M1. Depending upon the binary value of the bit being written, either the global write bit line GWBL12 or the complement global write bit line GWBLB12 will be discharged. Write driver includes an analogous pair of NMOS transistors M3 and M4 for controlling the charged or discharged state of the global write bit lines GWBL34 and GWBL34 during a write operation to one of the banks in the second pair 102 of banks. Depending upon the binary state of a data in signal (Din34) and its complement Dinb34, either the global write bit line GWBL34 or the complement global write bit line GWBLB34 will be discharged.

Consider the advantages of memory 100 over an architecture in which the sense amplifiers and the write drivers are integrated into the LDPs. Should each LDP include a sense amplifier, the memory will typically include a pair of data output lines from the sense amplifier to the corresponding GIO. These data output lines are complementary such that one remains charged whereas the other is discharged. The discharging of the data output line uses a substantial amount of power. In contrast, the global read bit lines disclosed herein are not discharged full rail to ground. Instead, one of the global bit lines in an active global bit line pair will be just partially discharged during a read operation. As compared to the full rail discharge of data output lines, the signaling over the global read bit lines disclosed herein saves power. In addition, the access time may remain the same or even be faster since the data output latch 510 is located adjacent to the sense amplifier 505 in each GIO. In contrast, if the sense amplifier is located in an LDP, there is a propagation delay over the data lines from the sense amplifier to the GIO's data output latch. Thus, the read access time remains the same or even is improved in the multi-bank architecture disclosed herein.

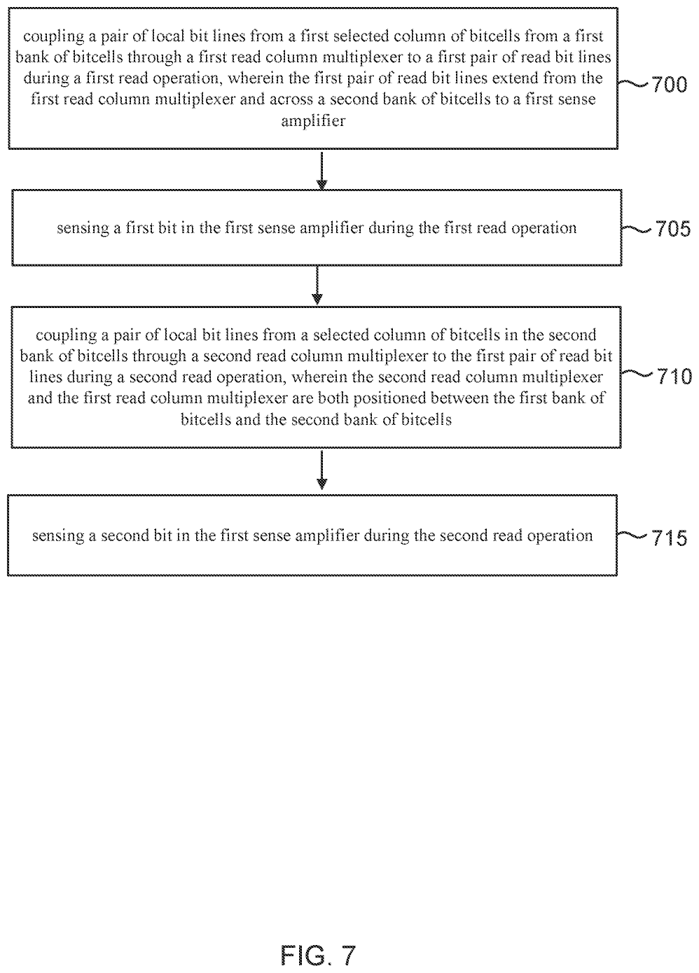

A method of reading to a multi-bank memory such as memory 100 will now be discussed with regard to the flowchart of FIG. 7. The method includes an act 700 of coupling a pair of local bit lines from a first selected column of bitcells from a first bank of bitcells through a first read column multiplexer to a first pair of read bit lines during a first read operation, wherein the first pair of read bit lines extend from the first read column multiplexer and across a second bank of bitcells to a first sense amplifier. The coupling of a pair of local bit lines through the read column multiplexer 205 is an example of act 700. The method also includes an act 705 of sensing a first bit in the first sense amplifier during the first read operation. A first sensing by the sense amplifier 505 is an example of act 705. The method further includes an act 710 of coupling a pair of local bit lines from a selected column of bitcells in the second bank of bitcells through a second read column multiplexer to the first pair of read bit lines during a second read operation, wherein the second read column multiplexer and the first read column multiplexer are both positioned between the first bank of bitcells and the second bank of bitcells. The coupling of a pair of local bit lines through the read column multiplexer 210 is an example of act 710. Finally, the method includes an act 715 of sensing a second bit in the first sense amplifier during the second read operation. A second sensing by the sense amplifier 505 is an example of act 715.

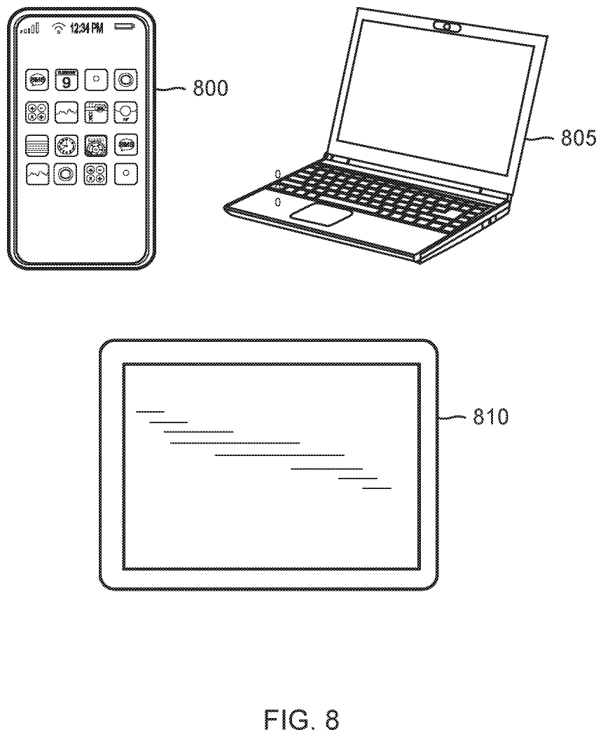

An integrated circuit having a multi-bank memory as disclosed herein may be incorporated in a wide variety of electronic systems. For example, as shown in FIG. 8, a cellular telephone 800, a laptop computer 805, and a tablet PC 810 may all include an integrated circuit having a multi-bank memory in accordance with the disclosure. Other exemplary electronic systems such as a music player, a video player, a communication device, and a personal computer may also be configured with an integrated circuit having a multi-bank memory constructed in accordance with the disclosure.

Some example implementations are described by the following numbered clauses:

Clause 1. A memory comprising:
a first bank of bitcells arranged into a first plurality of columns; a first plurality of read column multiplexers coupled to the first plurality of columns, the first plurality of read column multiplexers being located adjacent a first edge of the first bank of bitcells;
a second bank of bitcells arranged into a second plurality of columns, each column in the second plurality of columns extending from a first edge of the second bank of bitcells to a second edge of the second bank of bitcells, wherein the first edge of the second bank of bitcells is positioned to face the first edge of the first bank of bitcells;
a second plurality of read column multiplexers coupled to the second plurality of columns, the second plurality of read column multiplexers being located adjacent the first edge of the second bank of bitcells;
a plurality of read circuits being located adjacent the second edge of the second bank of bitcells; and
a first plurality of read bit lines coupled to the first plurality of read column multiplexers, the second plurality of read column multiplexers, and the plurality of read circuits.
   Clause 2. The memory of Clause 1, wherein the read column multiplexers from the first plurality of read column multiplexers and from the second plurality of read column multiplexers are arranged into pairs of read column multiplexers, each pair of read column multiplexers including a corresponding read column multiplexer from the first plurality of read column multiplexers and a corresponding read column multiplexer from the second plurality of read column multiplexers, and wherein each pair of read column multiplexers includes a pair of output nodes.
   Clause 3. The memory of claim 2, wherein the first plurality of read bit lines are arranged into pairs to form pairs of read bit lines, and wherein each pair of read bit lines is coupled to a corresponding pair of output nodes.
   Clause 4. The memory of clause 3, wherein each pair of read bit lines comprises a read bit line and a complement read bit line and each pair of output nodes comprises a positive output node and a complement output node, and wherein each read bit line is coupled to a corresponding positive output node and each complement read bit line is coupled to a corresponding complement output node.
   Clause 5. The memory of clause 2, wherein a plurality of local bit lines for the first bank of bitcells and for the second bank of bitcells are disposed within a first metal layer adjacent a semiconductor substrate.
   Clause 6. The memory of clause 5, wherein the first plurality of read bit lines are disposed within a second metal layer adjacent the first metal layer, the first metal layer is located between the semiconductor substrate and the second metal layer, and the first plurality of read bit lines are configured to extend across the second bank of bitcells from the first edge of the second bank of bitcells to the second edge of the second bank of bitcells.
   Clause 7. The memory of any of clauses 1-6, wherein the read circuits comprise a plurality of sense amplifiers, the memory further comprising:
a third bank of bitcells arranged into a third plurality of columns, each column in the third bank extending from a first edge of the third bank of bitcells to a second edge of the third bank of bitcells;
a third plurality of read column multiplexers coupled to the third plurality of columns, the third plurality of read column multiplexers being positioned adjacent the first edge of the third bank of bitcells;
a fourth bank of bitcells arranged into a fourth plurality of columns, wherein a first edge of the fourth bank of bitcells faces the first edge of the third bank of bitcells;
a fourth plurality of read column multiplexers coupled to the fourth plurality of columns, the fourth plurality of read column multiplexers being positioned adjacent the first edge of the fourth bank of bitcells; and
a second plurality of read bit lines coupled to the third plurality of read column multiplexers, the fourth plurality of read column multiplexers, and the plurality of sense amplifiers.
   Clause 8. The memory of clause 7, further comprising: a plurality of data output latches coupled to the plurality of sense amplifiers.
   Clause 9. The memory of any of clauses 1-8, wherein the memory comprises a static random-access memory.
   Clause 10. The memory of any of clauses 1-9, wherein the memory is incorporated into a cellular telephone.
   Clause 11. A method of reading from a memory, comprising:
coupling a pair of local bit lines from a first selected column of bitcells from a first bank of bitcells through a first read column multiplexer to a first pair of read bit lines during a first read operation, wherein the first pair of read bit lines extend from the first read column multiplexer and across a second bank of bitcells to a first sense amplifier;
sensing a first bit in the first sense amplifier during the first read operation;
coupling a pair of local bit lines from a selected column of bitcells in the second bank of bitcells through a second read column multiplexer to the first pair of read bit lines during a second read operation, wherein the second read column multiplexer and the first read column multiplexer are both positioned between the first bank of bitcells and the second bank of bitcells; and
sensing a second bit in the first sense amplifier during the second read operation.
   Clause 12. The method of clause 11, further comprising:
coupling a pair of local bit lines from a selected column of bitcells in a third bank of bitcells through a third read column multiplexer to a second pair of read bit lines during a third read operation, wherein the second pair of read bit lines extend from the third read column multiplexer and across a fourth bank of bitcells to the first sense amplifier; and
sensing a third bit in the first sense amplifier during the third read operation.
   Clause 13. The method of clause 12, further comprising:
coupling a pair of local bit lines from a selected column of bitcells in the fourth bank of bitcells through a fourth read column multiplexer to the second pair of read bit lines during a fourth read operation, wherein the third read column multiplexer and the fourth read column multiplexer are both positioned between the third bank of bitcells and the fourth bank of bitcells, and wherein the first sense amplifier is positioned between the second bank of bitcells and the fourth bank of bitcells; and
sensing a fourth bit in the first sense amplifier during the fourth read operation.
   Clause 14. The method of clause 11, further comprising:
coupling a pair of local bit lines from a second selected column of bitcells from the first bank of bitcells through a third read column multiplexer to a second pair of read bit lines during the first read operation, wherein the second pair of read bit lines extend from the third read column multiplexer and across the second bank of bitcells to a second sense amplifier positioned adjacent the first sense amplifier; and
sensing a third bit in the second sense amplifier during the first read operation.
   Clause 15. The method of clause 11, further comprising:
coupling a first pair of write bit lines to a third selected column of bitcells from the first bank of bitcells through a first write column multiplexer during a first write operation, wherein the first pair of write bit lines extend from the first write column multiplexer and across the second bank of bitcells to a first write driver; and
discharging a write bit line from the first pair of write bit lines in the first write driver to write a bit to a bitcell in the third selected column of bitcells during the first write operation.
   Clause 16. The method of clause 15, further comprising:
coupling the first pair of write bit lines through a second write column multiplexer to a pair of local bit lines from a selected column of bitcells in the second bank of bitcells during a second write operation, wherein the first write column multiplexer and the second write column multiplexer are both positioned between the first bank of bitcells and the second bank of bitcells; and
discharging a write bit line from the first pair of write bit lines in the first write driver to write a bit to a bitcell in the selected column of bitcells in the second bank of bitcells during the second write operation.
   Clause 17. The method of clause 16, further comprising:
coupling a pair of local bit lines from a selected column of bitcells in a third bank of bitcells through a third write column multiplexer to a second pair of write bit lines during a third write operation, wherein the second pair of write bit lines extend from the third write column multiplexer and across a fourth bank of bitcells to the first write driver; and
discharging through the first write driver a write bit line from the second pair of write bit lines to write a bit to a bitcell in the selected column of bitcells in the third bank of bitcells during the third write operation.
   Clause 18. The method of clause 17, further comprising:
coupling a pair of local bit lines from a selected column of bitcells in a fourth bank of bitcells through a fourth write column multiplexer to the second pair of write bit lines during a fourth write operation, wherein the third write column multiplexer and the fourth write column multiplexer are located between the third bank of bitcells and the fourth bank of bitcells; and
discharging through the first write driver a write bit line from the second pair of write bit lines to write a bit to a bitcell in the selected column of bitcells in the fourth bank of bitcells during the fourth write operation.
   Clause 19. A memory comprising:
a first bank of bitcells arranged into a first plurality of columns;
a first plurality of write column multiplexers coupled to the first plurality of columns, the first plurality of write column multiplexers being located adjacent a first edge of the first bank of bitcells;
a second bank of bitcells arranged into a second plurality of columns, each column in the second plurality of columns extending from a first edge of the second bank of bitcells to a second edge of the second bank of bitcells, wherein the first edge of the second bank of bitcells faces the first edge of the first bank of bitcells;
a second plurality of write column multiplexers coupled to the second plurality of columns, the second plurality of write column multiplexers being located adjacent the first edge of the second bank of bitcells;
a plurality of write drivers positioned adjacent the second edge of the second bank of bitcells; and
a first plurality of write bit lines coupled to the first plurality of write column multiplexers, the second plurality of write column multiplexers, and the plurality of write drivers.
   Clause 20. The memory of clause 19, wherein each column in the first plurality of columns and in the second plurality of columns includes a pair of local bit lines, and wherein each write column multiplexer includes a pair of input nodes and is configured to couple the pair of local bit lines from a selected one of the columns to its pair of input nodes.
   Clause 21. The memory of any of clauses 19-20, wherein the first bank of bitcells and the second bank of bitcells are both integrated into a semiconductor substrate, and wherein a plurality of local bit lines for the first bank of bitcells and for the second bank of bitcells are disposed within a first metal layer adjacent the semiconductor substrate.
   Clause 22. The memory of clause 21, wherein the first plurality of write bit lines are disposed within a second metal layer adjacent the first metal layer and are configured to extend across the second bank of bitcells from the first edge of the second bank of bitcells to the second edge of the second bank of bitcells, and further wherein the first metal layer is located between the semiconductor substrate and the second metal layer.
   Clause 23. The memory of any of clauses 19-22, wherein the first plurality of write bit lines are arranged into pairs to form pairs of write bit lines, and wherein each pair of write bit lines is coupled to a corresponding pair of input nodes.
   Clause 24. The memory of clause 23, wherein each pair of write bit lines comprises a write bit line and a complement write bit line and each pair of input nodes comprises a positive input node and a complement input node, and wherein each write bit line is coupled to a corresponding positive input node and each complement write bit line is coupled to a corresponding complement input node.
   Clause 25. The memory of any of clauses 19-24, further comprising:
a third bank of bitcells arranged into a third plurality of columns;
a third plurality of write column multiplexers coupled to the third plurality of columns, the third plurality of write column multiplexers positioned adjacent a first edge of the third bank of bitcells;
a fourth bank of bitcells arranged into a fourth plurality of columns, each column in the fourth plurality of columns extending from a first edge of the fourth bank of bitcells to a second edge of the fourth bank of bitcells, wherein the first edge of the fourth bank of bitcells faces the first edge of the third bank of bitcells;
a fourth plurality of write column multiplexers coupled to the fourth plurality of columns, the fourth plurality of write column multiplexers being located adjacent the first edge of the fourth bank of bitcells; and
a second plurality of write bit lines coupled to the third plurality of write column multiplexers, the fourth plurality of write column multiplexers, and the plurality of write drivers.
   Clause 26. A memory comprising:
a first pair of banks;
a second pair of banks;
a sense amplifier located between the first pair of banks and the second pair of banks;
a first read column multiplexer configured to couple a pair of local bit lines for an addressed column of bitcells from a first bank in the first pair of banks to a first pair of output nodes;
a second read column multiplexer configured to couple a pair of local bit lines for an addressed column of bitcells from a second bank in the first pair of banks to the first pair of output nodes; and
a first pair of read bit lines coupled between the first pair of output nodes and the sense amplifier.
   Clause 27. The memory of clause 26, further comprising:
a third read column multiplexer configured to couple a pair of local bit lines for an addressed column of bitcells from a third bank in the second pair of banks to a second pair of output nodes;
a fourth read column multiplexer configured to couple a pair of local bit lines for an addressed column of bitcells from a fourth bank in the second pair of banks to the second pair of output nodes; and
a second pair of read bit lines coupled between the second pair of output nodes and the sense amplifier.
   Clause 28. The memory of any of clauses 26-27, further comprising:
a write driver located between the first pair of banks and the second pair of banks;
a first write column multiplexer configured to couple a first pair of input nodes to a pair of local bit lines for an addressed column of bitcells from a third bank in the second pair of bank;
a second write column multiplexer configured to couple the first pair of input nodes to pair of local bit lines for the addressed column of bitcells from the second bank; and
a first pair of write bit lines coupled between the first pair of input nodes and the write driver.
   Clause 29. The memory of clause 28, further comprising:
a third write column multiplexer configured to couple a second pair of input nodes to a pair of local bit lines for an addressed column of bitcells from a third bank in the second pair of banks;
a fourth write column multiplexer configured to couple the second pair of input nodes to a pair of local bit lines for an addressed column of bitcells from a fourth bank in the second pair of banks; and
a second pair of write bit lines coupled between the second pair of input nodes and the write driver.
   Clause 30. The memory of any of causes 26-29, wherein the first bank has a first edge facing a first edge of the second bank, and wherein the second bank has a second edge facing the sense amplifier.

As those of some skill in this art will by now appreciate and depending on the particular application at hand, many modifications, substitutions and variations can be made in and to the materials, apparatus, configurations and methods of use of the devices of the present disclosure without departing from the scope thereof as defined by the appended claims. In light of this, the scope of the present disclosure should not be limited to that of the particular implementations illustrated and described herein, as they are merely by way of some examples thereof, but rather, should be fully commensurate with that of the claims appended hereafter and their functional equivalents.

What is claimed is:

1. A memory comprising:
a first bank of bitcells arranged into a first plurality of columns;
a first plurality of read column multiplexers coupled to the first plurality of columns, the first plurality of read column multiplexers being located adjacent a first edge of the first bank of bitcells;
a second bank of bitcells arranged into a second plurality of columns, wherein the first edge of the second bank of bitcells is positioned to face the first edge of the first bank of bitcells;
a second plurality of read column multiplexers coupled to the second plurality of columns, the second plurality of read column multiplexers being located adjacent the first edge of the second bank of bitcells;
a plurality of read circuits being located adjacent a second edge of the second bank of bitcells; and
a first plurality of read bit lines coupled to the first plurality of read column multiplexers, the second plurality of read column multiplexers, and the plurality of sense amplifiers.

2. The memory of claim 1, wherein the read column multiplexers from the first plurality of read column multiplexers and from the second plurality of read column multiplexers are arranged into pairs of read column multiplexers, each pair of read column multiplexers including a corresponding read column multiplexer from the first plurality of read column multiplexers and a corresponding read column multiplexer from the second plurality of read column multiplexers, and wherein each pair of read column multiplexers couples to a pair of output nodes.

3. The memory of claim 2, wherein the first plurality of read bit lines are arranged into pairs to form pairs of read bit lines, and wherein each pair of read bit lines is coupled to a corresponding pair of output nodes.

4. The memory of claim 3, wherein each pair of read bit lines comprises a read bit line and a complement read bit line and each pair of output nodes comprises a positive output node and a complement output node, and wherein each read bit line is coupled to a corresponding positive output node and each complement read bit line is coupled to a corresponding complement output node.

5. The memory of claim 2, wherein a plurality of local bit lines for the first bank of bitcells and for the second bank of bitcells are disposed within a first metal layer adjacent a semiconductor substrate.

6. The memory of claim 5, wherein the first plurality of read bit lines are disposed within a second metal layer adjacent the first metal layer, the first metal layer is located between the semiconductor substrate and the second metal layer, and the first plurality of read bit lines are configured to extend across the second bank of bitcells from the first edge of the second bank of bitcells to the second edge of the second bank of bitcells.

7. The memory of claim 1, wherein the read circuits comprise a plurality of sense amplifiers, the memory further comprising:
a third bank of bitcells arranged into a third plurality of columns, each column in the third bank extending from a first edge of the third bank of bitcells to a second edge of the third bank of bitcells;
a third plurality of read column multiplexers coupled to the third plurality of columns, the third plurality of read column multiplexers being positioned adjacent the first edge of the third bank of bitcells;
a fourth bank of bitcells arranged into a fourth plurality of columns, wherein a first edge of the fourth bank of bitcells faces the first edge of the third bank of bitcells;
a fourth plurality of read column multiplexers coupled to the fourth plurality of columns, the fourth plurality of read column multiplexers being positioned adjacent the first edge of the fourth bank of bitcells; and
a second plurality of read bit lines coupled to the third plurality of read column multiplexers, the fourth plurality of read column multiplexers, and the plurality of sense amplifiers.

8. The memory of claim 1, further comprising:
a plurality of data output latches coupled to the plurality of sense amplifiers.

9. The memory of claim 1, wherein the memory comprises a static random-access memory.

10. The memory of claim 1, wherein the memory is incorporated into a cellular telephone.

11. A method of reading from a memory, comprising:
coupling a pair of local bit lines from a first selected column of bitcells from a first bank of bitcells through a first read column multiplexer to a first pair of read bit lines during a first read operation, wherein the first pair of read bit lines extend from the first read column multiplexer and across a second bank of bitcells to a first sense amplifier;
sensing a first bit in the first sense amplifier during the first read operation;
coupling a pair of local bit lines from a selected column of bitcells in the second bank of bitcells through a second read column multiplexer to the first pair of read bit lines during a second read operation, wherein the second read column multiplexer and the first read column multiplexer are both positioned between the first bank of bitcells and the second bank of bitcells; and
sensing a second bit in the first sense amplifier during the second read operation.

12. The method of claim 11, further comprising:
coupling a pair of local bit lines from a selected column of bitcells in a third bank of bitcells through a third read column multiplexer to a second pair of read bit lines during a third read operation, wherein the second pair of read bit lines extend from the third read column multiplexer and across a fourth bank of bitcells to the first sense amplifier; and
sensing a third bit in the first sense amplifier during the third read operation.

13. The method of claim 12, further comprising:
coupling a pair of local bit lines from a selected column of bitcells in the fourth bank of bitcells through a fourth read column multiplexer to the second pair of read bit lines during a fourth read operation, wherein the third read column multiplexer and the fourth read column multiplexer are both positioned between the third bank of bitcells and the fourth bank of bitcells, and wherein the first sense amplifier is positioned between the second bank of bitcells and the fourth bank of bitcells; and
sensing a fourth bit in the first sense amplifier during the fourth read operation.

14. The method of claim 11, further comprising:
coupling a pair of local bit lines from a second selected column of bitcells from the first bank of bitcells through a third read column multiplexer to a second pair of read bit lines during the first read operation, wherein the second pair of read bit lines extend from the third read column multiplexer and across the second bank of bitcells to a second sense amplifier positioned adjacent the first sense amplifier; and
sensing a third bit in the second sense amplifier during the first read operation.

15. The method of claim 11, further comprising:
coupling a first pair of write bit lines to a third selected column of bitcells from the first bank of bitcells through a first write column multiplexer during a first write operation, wherein the first pair of write bit lines extend from the first write column multiplexer and across the second bank of bitcells to a first write driver; and
discharging a write bit line from the first pair of write bit lines in the first write driver to write a bit to a bitcell in the third selected column of bitcells during the first write operation.

16. The method of claim 15, further comprising:
coupling the first pair of write bit lines through a second write column multiplexer to a pair of local bit lines from a selected column of bitcells in the second bank of bitcells during a second write operation, wherein the first write column multiplexer and the second write column multiplexer are both positioned between the first bank of bitcells and the second bank of bitcells; and
discharging a write bit line from the first pair of write bit lines in the first write driver to write a bit to a bitcell in the selected column of bitcells in the second bank of bitcells during the second write operation.

17. The method of claim 16, further comprising:
coupling a pair of local bit lines from a selected column of bitcells in a third bank of bitcells through a third write column multiplexer to a second pair of write bit lines during a third write operation, wherein the second pair of write bit lines extend from the third write column multiplexer and across a fourth bank of bitcells to the first write driver; and
discharging through the first write driver a write bit line from the second pair of write bit lines to write a bit to a bitcell in the selected column of bitcells in the third bank of bitcells during the third write operation.

18. The method of claim 17, further comprising:
coupling a pair of local bit lines from a selected column of bitcells in a fourth bank of bitcells through a fourth write column multiplexer to the second pair of write bit lines during a fourth write operation, wherein the third write column multiplexer and the fourth write column multiplexer are located between the third bank of bitcells and the fourth bank of bitcells; and
discharging through the first write driver a write bit line from the second pair of write bit lines to write a bit to a bitcell in the selected column of bitcells in the fourth bank of bitcells during the fourth write operation.

19. A memory comprising:
a first bank of bitcells arranged into a first plurality of columns;
a first plurality of write column multiplexers coupled to the first plurality of columns, the first plurality of write column multiplexers being located adjacent a first edge of the first bank of bitcells;
a second bank of bitcells arranged into a second plurality of columns, each column in the second plurality of columns extending from a first edge of the second bank of bitcells to a second edge of the second bank of bitcells, wherein the first edge of the second bank of bitcells faces the first edge of the first bank of bitcells;
a second plurality of write column multiplexers coupled to the second plurality of columns, the second plurality of write column multiplexers being located adjacent the first edge of the second bank of bitcells;
a plurality of write drivers positioned adjacent the second edge of the second bank of bitcells; and
a first plurality of write bit lines coupled to the first plurality of write column multiplexers, the second plurality of write column multiplexers, and the plurality of write drivers.

20. The memory of claim 19, wherein each column in the first plurality of columns and in the second plurality of columns includes a pair of local bit lines, and wherein each write column multiplexer includes a pair of input nodes and is configured to couple the pair of local bit lines from a selected one of the columns to its pair of input nodes.

21. The memory of claim 19, wherein the first bank of bitcells and the second bank of bitcells are both integrated into a semiconductor substrate, and wherein a plurality of local bit lines for the first bank of bitcells and for the second bank of bitcells are disposed within a first metal layer adjacent the semiconductor substrate.

22. The memory of claim 21, wherein the first plurality of write bit lines are disposed within a second metal layer adjacent the first metal layer and are configured to extend across the second bank of bitcells from the first edge of the second bank of bitcells to the second edge of the second bank of bitcells, and further wherein the first metal layer is located between the semiconductor substrate and the second metal layer.

23. The memory of claim 19, wherein the first plurality of write bit lines are arranged into pairs to form pairs of write bit lines, and wherein each pair of write bit lines is coupled to a corresponding pair of input nodes.

24. The memory of claim 23, wherein each pair of write bit lines comprises a write bit line and a complement write bit line and each pair of input nodes comprises a positive input node and a complement input node, and wherein each write bit line is coupled to a corresponding positive input node and each complement write bit line is coupled to a corresponding complement input node.

25. The memory of claim 19, further comprising:
a third bank of bitcells arranged into a third plurality of columns;
a third plurality of write column multiplexers coupled to the third plurality of columns, the third plurality of write column multiplexers positioned adjacent a first edge of the third bank of bitcells;
a fourth bank of bitcells arranged into a fourth plurality of columns, each column in the fourth plurality of columns extending from a first edge of the fourth bank of bitcells to a second edge of the fourth bank of bitcells, wherein the first edge of the fourth bank of bitcells faces the first edge of the third bank of bitcells;
a fourth plurality of write column multiplexers coupled to the fourth plurality of columns, the fourth plurality of write column multiplexers being located adjacent the first edge of the fourth bank of bitcells; and
a second plurality of write bit lines coupled to the third plurality of write column multiplexers, the fourth plurality of write column multiplexers, and the plurality of write drivers.

26. A memory comprising:
a first pair of banks;
a second pair of banks;
a sense amplifier located between the first pair of banks and the second pair of banks;
a first read column multiplexer configured to couple a pair of local bit lines for an addressed column of bitcells from a first bank in the first pair of banks to a first pair of output nodes;
a second read column multiplexer configured to couple a pair of local bit lines for an addressed column of bitcells from a second bank in the first pair of banks to the first pair of output nodes; and
a first pair of read bit lines coupled between the first pair of output nodes and the sense amplifier.

27. The memory of claim 26, further comprising:
a third read column multiplexer configured to couple a pair of local bit lines for an addressed column of bitcells from a third bank in the second pair of banks to a second pair of output nodes;
a fourth read column multiplexer configured to couple a pair of local bit lines for an addressed column of bitcells from a fourth bank in the second pair of banks to the second pair of output nodes; and
a second pair of read bit lines coupled between the second pair of output nodes and the sense amplifier.

28. The memory of claim 26, further comprising:
a write driver located between the first pair of banks and the second pair of banks;
a first write column multiplexer configured to couple a first pair of input nodes to a pair of local bit lines for an addressed column of bitcells from a third bank in the second pair of banks;
a second write column multiplexer configured to couple the first pair of input nodes to pair of local bit lines for an addressed column of bitcells from a fourth bank in the second pair of banks; and
a first pair of write bit lines coupled between the first pair of input nodes and the write driver.

29. The memory of claim 28, further comprising:
a third write column multiplexer configured to couple a second pair of input nodes to a pair of local bit lines for an addressed column of bitcells from a third bank in the second pair of banks;
a fourth write column multiplexer configured to couple the second pair of input nodes to a pair of local bit lines for an addressed column of bitcells from a fourth bank in the second pair of banks; and
a second pair of write bit lines coupled between the second pair of input nodes and the write driver.

30. The memory of claim 26, wherein the first bank has a first edge facing a first edge of the second bank, and wherein the second bank has a second edge facing the sense amplifier.
